(19) United States
(12) Patent Application Publication
(10) Pub. No.: US 2023/0059431 A1
(43) Pub. Date: Feb. 23, 2023

(54) STACKED DIE INTEGRATED CIRCUIT (IC) PACKAGE EMPLOYING INTERPOSER FOR COUPLING AN UPPER STACKED DIE(S) TO A PACKAGE SUBSTRATE FOR PACKAGE HEIGHT REDUCTION, AND RELATED FABRICATION METHODS

(71) Applicant: QUALCOMM Incorporated, San Diego, CA (US)

(72) Inventors: Krishna Vemuri, San Diego, CA (US); Jinseong Kim, Escondido, CA (US)

(21) Appl. No.: 17/409,481

(22) Filed: Aug. 23, 2021

(51) Int. Cl. H01L 25/065; H01L 23/31; H01L 23/538; H01L 25/00

(52) U.S. Cl. CPC H01L 25/0657; H01L 23/3128; H01L 23/5383; H01L 23/5385; H01L 23/5386; H01L 23/5389; H01L 25/50; H01L 2225/0651; H01L 2225/06517; H01L 2225/06558; H01L 2225/06586

(57) ABSTRACT

Stacked die integrated circuit (IC) package employing an interposer for electrically coupling an upper stacked die(s) to a package substrate for package height reduction, and related fabrication methods. To reduce the height of the IC package while providing for stacked dies to be electrically coupled to a package substrate, the IC package includes an interposer. The stacked dies are disposed between the package substrate and the interposer. One or more wires are coupled (e.g., wire bonded) between the upper die and the interposer to provide an electrical connection between the upper die and the interposer. One or more electrical interconnects (e.g., conductive pillars) are coupled between the interposer and the package substrate to route electrical connections between the upper die and the package substrate. Thus, the upper die can be electrically coupled to the package substrate without requiring an additional clearance area above the upper die for wire bonds.

### BACKGROUND

### I. Field of the Disclosure

The field of the disclosure relates to integrated circuit (IC) packages, and more particularly to wire bonding of a semiconductor die to a package substrate in the IC package.

### II. Background

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that are mounted on and electrically coupled to a package substrate to provide physical support and an electrical interface to the die(s). The package substrate includes one or more metallization layers that include electrical traces (e.g., metal lines) with vertical interconnect accesses (vias) coupling the electrical traces together between adjacent metallization layers to provide electrical interfaces between the die(s). The die(s) is electrically interfaced to metal interconnects exposed in a top or outer layer of the package substrate to electrically couple the semiconductor die(s) to the electrical traces of the package substrate. The package substrate includes an outer metallization layer coupled to external metal interconnects (e.g., solder bumps) to provide an external interface between the die(s) in the IC package for mounting the IC package on a circuit board to interface the die(s) with other circuitry.

Some IC packages are known as “hybrid” IC packages which include multiple dies for different purposes or applications. For example, a hybrid IC package may include a modem die as part of a front-end circuitry for supporting a communications interface. The hybrid IC package could also include one or more memory dies that provide memory to support data storage and access by the modem die, such as for buffering and outgoing data to be modulated and/or demodulated data. Thus, in these hybrid IC packages, it is conventional to stack the multiple dies on top of each other in the IC package. The bottom-most die that is directly adjacent to the package substrate of the IC package is electrically coupled through die interconnects to metal interconnects in an upper metallization layer of the package substrate. Other stacked dies that are not directly adjacent to the package substrate of the IC package can be electrically coupled by wire bonds to a metallization layer of the package substrate. Electrical connections between the memory die(s) and the modem die are formed through electrical connections in the package substrate.

### SUMMARY OF THE DISCLOSURE

Aspects disclosed herein include a stacked die integrated circuit (IC) package employing an interposer for electrically coupling an upper stacked die(s) to a package substrate for package height reduction. Related fabrication methods are also disclosed. The IC package includes a package substrate that supports stacked dies. The package substrate includes one or more metallization layers that each include metal interconnects to provide electrical signal routing between external interconnects and the dies, and between dies within the IC package. The stacked dies are electrically coupled to the package substrate for signal routing. A lower die in the IC package can be directly electrically coupled to the package substrate (e.g., through interconnect bumps) coupling the active side of the lower die to metal interconnects in an upper metallization layer of the package substrate. However, an upper die(s) stacked above the lower die in the IC package is not located directly adjacent to the package substrate. Wire bonds can be employed to couple an active side of an upper die to the package substrate. However, wire bonds may have to be oriented to extend above the upper die to have sufficient clearance area to extend outward and then downward to the package substrate without interfering with the lower die or other package components. Wire bonds may also require a minimum bend radius so as to not be damaged, which requires a certain additional clearance area above the upper die beyond a normal area tolerance between the upper die and the top surface of an overmolding of the IC package. This additional clearance area contributes towards the overall height of the IC package that may be undesired.

Thus, in exemplary aspects, to reduce the height of the IC package while still providing for a stacked die arrangement to be electrically coupled to the package substrate, the IC package includes an interposer. The stacked dies are disposed between the package substrate and the interposer. One or more wires are coupled (e.g., wire bonded) between an active side of the upper die and the interposer to provide an electrical connection between the upper die and the interposer. One or more electrical interconnects (e.g., conducive pillars) are coupled between the interposer and the package substrate to route electrical connections between the wires coupled to the upper die and the package substrate. In this manner, the upper die can be electrically coupled to the package substrate without requiring an additional clearance area for wire bonds to be coupled the upper die and down to the package substrate. The height of the interposer adding to the overall height of the IC package may be less than the height of a clearance area that would be needed for wire bonding the upper die to the package substrate.

In this regard, in one exemplary aspect, an IC package is disclosed. The IC package includes a package substrate. The IC package also includes an interposer. The IC package also includes a first die electrically coupled to the package substrate. The IC package also includes a second die disposed between the first die and the interposer. The IC package also includes one or more second wires coupled to the second die and the interposer. The IC package also includes one or more electrical interconnects coupled to the interposer and the package substrate and each electrically coupling a second wire among the one or more second wires to the package substrate.

In another exemplary aspect, a method of fabricating an IC package is disclosed. The method includes providing a package substrate. The method also includes providing an interposer. The method also includes electrically coupling a first die to the package substrate. The method also includes disposing a second die between the first die and the interposer. The method also includes coupling one or more second wires to the second die and the interposer. The method also includes coupling one or more electrical interconnects to the package substrate and to the interposer to electrically couple a second wire among the one or more second wires to the package substrate.

### BRIEF DESCRIPTION OF THE FIGURES

FIGS. 1A and 1B are side views of an exemplary integrated circuit (IC) package that includes two (2) stacked semiconductor dies (“dies”) between a package substrate and an interposer, wherein a lower die is directly electrically coupled to the package substrate and an upper die is electrically coupled to the package substrate through an interposer for package height reduction;

FIG. 2A is a side view of an IC package that includes stacked dies, but wherein the upper die is directly electrically coupled to the package substrate;

FIG. 2B is a side view of the IC package in FIGS. 1A and 1B for height comparison to the IC package in FIG. 2A;

FIGS. 3A and 3B are side views of another exemplary IC package that includes three (3) stacked dies between a package substrate and an interposer, wherein a lower die is directly electrically coupled to the package substrate and an upper die is electrically coupled to the package substrate through an interposer for package height reduction;

FIG. 4 is a flowchart illustrating an exemplary process of fabricating an IC package that includes stacked dies between a package substrate and an interposer, wherein a lower die is directly electrically coupled to the package substrate and an upper die is electrically coupled to the package substrate through an interposer for package height reduction, including, but not limited to, the IC packages in FIGS. 1A-1B and 3A-3B;

FIG. 5 is a flowchart illustrating an exemplary process for fabricating an interposer and upper die sub-package to be included in an IC package that includes stacked dies between a package substrate and an interposer, wherein a lower die is directly electrically coupled to the package substrate and an upper die is electrically coupled to the package substrate through an interposer for package height reduction, including, but not limited to, the IC packages in FIGS. 1A-1B and 3A-3B;

FIGS. 6A-6C illustrate exemplary fabrication stages during fabrication of the interposer and upper die sub-package for an IC package, including, but not limited to, the IC packages in FIGS. 1A-1B and 3A-3B, and according to the exemplary fabrication process in FIG. 5;

FIG. 7 is a flowchart illustrating an exemplary process for fabricating a package substrate and lower die sub-package to be included in an IC package that includes stacked dies between a package substrate and an interposer, wherein a lower die is directly electrically coupled to the package substrate and an upper die is electrically coupled to the package substrate through an interposer for package height reduction, including, but not limited to, the IC packages in FIGS. 1A-1B and 3A-3B;

FIGS. 8A-8C illustrate exemplary fabrication stages during fabrication of the package substrate and lower die sub-package for an IC package, including, but not limited to, the IC packages in FIGS. 1A-1B and 3A-3B, and according to the exemplary fabrication process in FIG. 7;

FIGS. 9A and 9B are a flowchart illustrating an exemplary process for assembling an interposer and upper die sub-package, including, but not limited to, the interposer and upper die sub-package in FIG. 6C, with a package substrate and lower die sub-package, including, but not limited to, the package substrate and lower die sub-package in FIG. 8C, for fabricating an IC package that includes stacked dies between a package substrate and an interposer, wherein a lower die is directly electrically coupled to the package substrate and an upper die is electrically coupled to the package substrate through an interposer for package height reduction, including, but not limited to, the IC packages in FIGS. 1A-1B and 3A-3B;

FIGS. 10A-10C illustrate exemplary fabrication stages during assembly of the interposer and upper die sub-package with the package substrate and lower die sub-package to form an IC package, including, but not limited to, the IC packages in FIGS. 1A-1B and 3A-3B, and according to the exemplary fabrication process in FIGS. 9A and 9B;

FIG. 11 is a block diagram of an exemplary processor-based system that can include components that can include an IC package with stacked dies between a package substrate and an interposer, wherein a lower die and intermediate dies are directly electrically coupled to the package substrate, and an upper die is electrically coupled to the package substrate through an interposer for package height reduction, including, but not limited, to the IC packages FIGS. 1A-1B, 3A-3B, 6A-6C, 8A-8C and 10A-10C, and according to the exemplary fabrication processes in FIGS. 5, 7, and 9A-9B; and

FIG. 12 is a block diagram of an exemplary wireless communications device that includes radio-frequency (RF) components that can include an IC package with stacked dies between a package substrate and an interposer, wherein a lower die and intermediate dies are directly electrically coupled to the package substrate, and an upper die is electrically coupled to the package substrate through an interposer for package height reduction, including, but not limited, to the IC packages FIGS. 1A-1B, 3A-3B, 6A-6C, 8A-8C and 10A-10C, and according to the exemplary fabrication processes in FIGS. 5, 7, and 9A-9B.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include a stacked die integrated circuit (IC) package employing an interposer for electrically coupling an upper stacked die(s) to a package substrate for package height reduction. Related fabrication methods are also disclosed. The IC package includes a package substrate that supports stacked dies. The package substrate includes one or more metallization layers that each include metal interconnects to provide electrical signal routing between external interconnects and the dies, and between dies within the IC package. The stacked dies are electrically coupled to the package substrate for signal routing. A lower die in the IC package can be directly electrically coupled to the package substrate (e.g., through interconnect bumps) coupling the active side of the lower die to metal interconnects in an upper metallization layer of the package substrate. However, an upper die(s) stacked above the lower die in the IC package is not located directly adjacent to the package substrate. Wire bonds can be employed to couple an active side of an upper die to the package substrate. However, wire bonds may have to be oriented to extend above the upper die to have sufficient clearance area to extend outward and then downward to the package substrate without interfering with the lower die or other package components. Wire bonds may also require a minimum bend radius so as to not be damaged, which requires a certain additional clearance area above the upper die beyond a normal area tolerance between the upper die and the top surface of an overmolding of the IC package. This additional clearance area contributes towards the overall height of the IC package that may be undesired.

Thus, in exemplary aspects, to reduce the height of the IC package while still providing for a stacked die arrangement to be electrically coupled to the package substrate, the IC package includes an interposer. The stacked dies are disposed between the package substrate and the interposer. One or more wires are coupled (e.g., wire bonded) between an active side of the upper die and the interposer to provide an electrical connection between the upper die and the interposer. One or more electrical interconnects (e.g., conducive pillars) are coupled between the interposer and the package substrate to route electrical connections between the wires coupled to the upper die and the package substrate. In this manner, the upper die can be electrically coupled to the package substrate without requiring an additional clearance area for wire bonds to be coupled the upper die and down to the package substrate. The height of the interposer adding to the overall height of the IC package may be less than the height of a clearance area that would be needed for wire bonding the upper die to the package substrate.

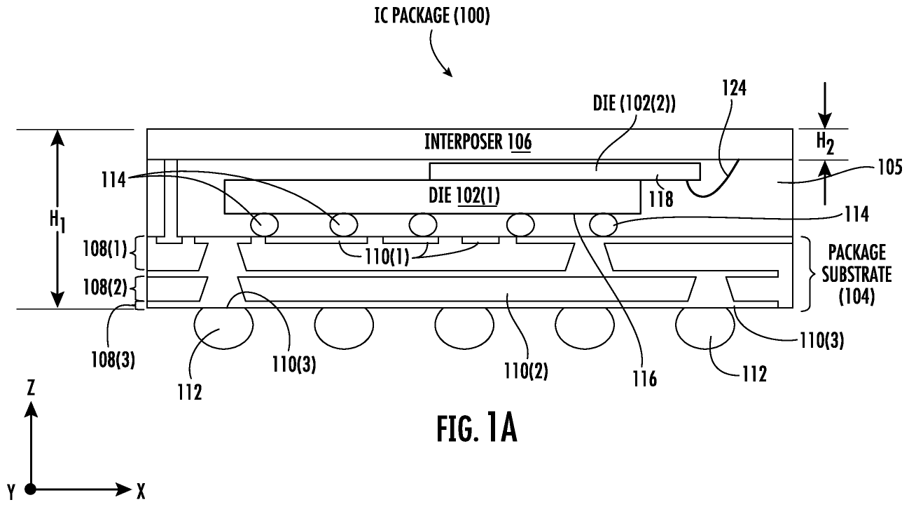

In this regard, FIG. 1A is a side view of an exemplary IC package 100 that includes two (2) stacked dies 102(1), 102(2) disposed between a package substrate 104 and an interposer 106. The first die 102(1) is considered a “lower” die in this example, meaning that is disposed below the second, “upper” die 102(2) in the vertical, Z-axis direction as shown in FIG. 1A. The lower die 102(1) is disposed adjacent to the package substrate 104. The upper die 102(2) is disposed adjacent to the interposer 106. An overmold 105 (e.g., an epoxy) surrounds the stacked dies 102(1), 102(2) between the interposer 106 and the package substrate 104. The stacked dies 102(1), 102(2) include ICs for performing electronic functions according to their design. For example, the lower die 102(1) may be a communications modem. The upper die 102(2) may be a memory device that is designed to provide data storage and access to the modem in the lower die 102(1), such as for buffering of data to be modulated for transmission as radio-frequency (RF) signals and demodulated data from received RF signals.

The package substrate 104 supports the stacked dies 102(1), 102(2) and also includes metallization layers 108(1), 108(2) that each include metal interconnects 110(1), 110(2) (e.g., metal lines, metal traces, vertical interconnect accesses (vias)) that can provide electrical signal routing between external interconnects 112 (e.g., solder bumps) and the dies 102(1), 102(2). The metallization layers 108(1), 108(2) could be formed as laminate substrates that are bonded to each other and/or as redistributed layers (RDLs). Although not shown, note that the package substrate 104 could also include a core section to be a cored substrate, as opposed to a coreless substrate. The package substrate 104 in this example includes an external metallization layer 108(3) that has metal interconnects 110(3) exposed from the package substrate 104 wherein the external interconnects 112 can be coupled to the metal interconnects 110(3) to provide external signal routing access to the IC package 100. For example, the external interconnects 112 may be soldered to contacts on a printed circuit board (PCB) to physically mount the IC package 100 on the PCB and to couple the IC package 100 to other circuitry. Certain metal interconnects 110(1), 110(2) in the package substrate 104 can also be designated to provide internal signal routing between the dies 102(1), 102(2) themselves.

With continuing reference to FIG. 1A, the stacked dies 102(1), 102(2) are electrically coupled to the package substrate 104 for signal routing. The lower die 102(1) in the IC package 100 is shown as being directly electrically coupled to the package substrate 104 through interconnect bumps 114. An active side 116 of the lower die 102(1) adjacent to the package substrate 104 is coupled to the interconnect bumps 114 which are coupled to the metal interconnects 110(1) in the upper metallization layer 108(1) of the package substrate 104. However, the upper die 102(2) stacked above the lower die 102(1) in the IC package 100 is not located directly adjacent to the package substrate 104. Wire bonds could be employed to couple an active side 118 of the upper die 102(2) directly to the metal interconnects 110(1) in the upper metallization layer 108(1) of the package substrate 104. However, wire bonds may have to be oriented to extend above the upper die 102(2) in the vertical (Z-axis) direction to have sufficient clearance area to extend outward and then downward to the package substrate 104 without interfering with the lower die 102(1) or other package components. Wire bonds may also require a minimum bend radius so as to not be damaged, which would require a certain additional clearance area in the IC package 100 above the upper die 102(2) to have sufficient area for such wire bonds and to accommodate their required minimum bend radius. This additional clearance area, if present, would contribute towards the overall height H₁ of the IC package 100 that may be undesired.

Thus, as shown in the additional side view of the IC package 100 in FIG. 1B, to reduce the height of the IC package 100 while still providing for the stacked dies 102(1), 102(2) to be electrically coupled to the package substrate 104, the IC package 100 in FIG. 1B includes the interposer 106. The interposer 106 provides electrical interface routing between one component and another, which in this case is between the upper die 102(2) and electrical interconnects 120 (e.g., metal pillars, metal posts, metal vias) coupling the interposer 106 to the package substrate 104. For example, the interposer 106 may include one or more metallization layers 122 that each include one or more metal interconnects that are electrically coupled to the upper die 102(2) and also are electrically coupled to one or more electrical interconnects 120 for routing of electrical signals from the upper die 102(2) to the package substrate 104. In this manner, the upper die 102(2) is electrically coupled to the package substrate 104 for signal routing to the external interconnects 112 and/or to other metal interconnects 110(1), 110(2) in the metallization layers 108(1), 108(2) that are coupled to the lower die 102(1) for die-to-die connections. As shown in FIG. 1B, in this example, one or more wires 124 are coupled (e.g., wire bonded) between the active side 118 of the upper die 102(2) and the interposer 106 to provide electrical interface connections between the upper die 102(2) and the interposer 106. The electrical interconnects 120 are coupled between the interposer 106 and the package substrate 104 to route electrical connections between the wires 124 coupled to the upper die 102(2) and the package substrate 104. In this manner, the upper die 102(2) can be electrically coupled to the package substrate 104 without requiring an additional clearance area for wire bonds to be coupled to the active side 118 of the upper die 102(2), extending up above the upper die 102(2) in the vertical (Z-axis) direction and then back down to the package substrate 104. The height H₂ of the interposer 106 adding to the overall height H₁ of the IC package 100 may be less than the additional height of overmold 105 that would be needed to provide an additional clearance area above the upper die 102(2) for wire bonding the upper die 102(2) to the package substrate 104. For example, the height H₂ of the interposer 106 may be 50 micrometers (μm).

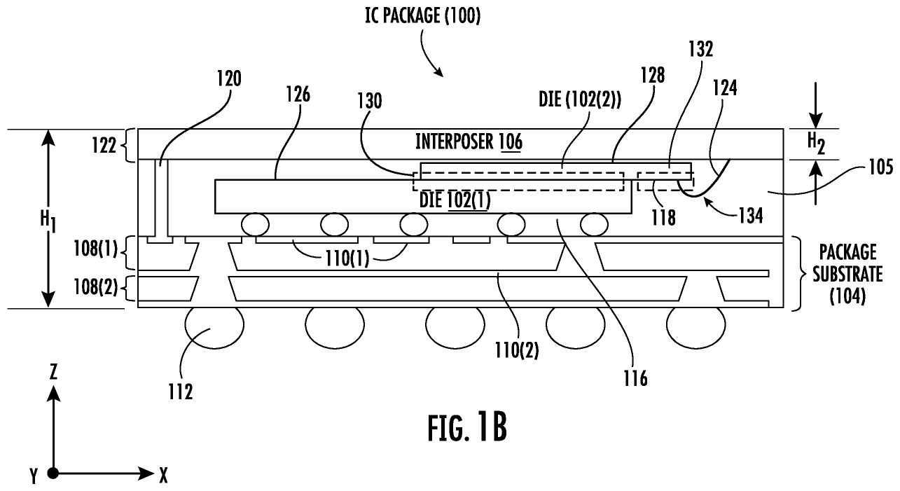

To further illustrate exemplary differences between the IC package 100 in FIGS. 1A and 1B that includes the interposer 106 for providing electrical connections between the upper die 102(2) and the package substrate 104, and an IC package that would use wire bonding to electrically connect the upper die 102(2) to the package substrate 104, FIGS. 2A and 2B are provided. FIG. 2B is the side view of the IC package 100 in FIG. 1A. As shown therein, the IC package 100 has an overall height H₁ with the interposer having a height H₂ that contributes the overall height H1 of the IC package 100. FIG. 2A is a side view of an alternative IC package 200 that includes the same package substrate 104 and stacked dies 102(1), 102(2) as in the IC package 100 in FIG. 1A. However, as shown in FIG. 2A, the upper IC die 102(1) is wire bonded through wires 202 to the package substrate 104. To provide for the wires 202 to be connected to the package substrate 104, the wires 202 have a bent portion 204 that extends upward from the upper die 102(2) in the vertical (Z-axis) direction and then extends outward in the horizontal (X-axis) direction and bends back down toward the package substrate 104 to have a clear path for being routed to the package substrate 104. The minimum radius of the bent portion 204 as well as the angle Θ1 at which the wires 202 need to extend down to the package substrate 104 dictate the minimum wire bond clearance area 205 of height H₄ above the upper die 102(2) that must be reserved for the wires 202. Also, there is additional area 206 above the wire bond clearance area 205 of height H₅ need to provide a tolerance between an upper surface 208 of an overmold 210 for the IC package 200. Thus, by providing the wire bonding between the upper die 102(2) and the package substrate 104 in the IC package 200 in FIG. 2A, the minimum wire bond clearance area 205 of height H₄ is added that contributes to the overall height H₃ of the IC package 200. Note that in this example, the overall height H₃ of the IC package 200 is greater than the overall height H₁ of the IC package 100 in FIG. 1A employing the interposer 106. For example, the height H₂ of the interposer 106 may be 50 μm vs. the height of the minimum wire bond clearance area 205 and additional area 206 of 125 μm providing for an extra 75 μm difference in the overall height H₃ of the IC package 200 in FIG. 2A versus the overall height H₁ of the IC package 100 in FIGS. 1A-1B and 2B.

With reference back to FIG. 1B, the lower die 102(1) of the IC package 100 has an inactive side 126 on an opposite side of the active side 116. The active side 118 of the upper die 102(2) is adjacent to the inactive side 126 of the lower die 102(4) in this example. At least a portion of the active side 118 of the upper die 102(2) may be bonded (e.g., through an epoxy or compression bond) to at least a portion of the inactive side 126 of the lower die 102(1). The upper die 102(2) has an inactive side 128 that is on an opposite side of the active side 118 of the upper die 102(2). The wires 124 are coupled to the active side 118 of the upper die 102(2) and also coupled the interposer 106 to electrically couple the upper die 102(2) to the interposer 106. In this example, to make room for the wires 124 to be coupled between the upper die 102(2) and the interposer 106, the upper die 102(2) is staggered to only be partially overlapping of the lower die 102(1) in the horizontal (X-axis) direction. In this regard, the active side 118 of the upper die 102(2) includes a first active side portion 130 overlapping a portion of the inactive side 126 of the lower die 102(2) in a vertical (Z-axis) direction and a second active side portion 132 not overlapping the lower die 102(1) in the vertical (Z-axis) direction. In this manner, there is room for the wires 124 to extend downward from the active side 118 of the upper die 102(2) towards the package substrate 104 and then bend back upwards towards the interposer 106 to then extend and couple to the interposer 106. This arrangement avoids a bent section 134 of the wires 124 extending above the upper die 102(2) in the vertical direction thereby requiring additional area above the upper die 102(2) to be reserved, which would increase the height of the IC package 100. In this example, the wires 124 include a concave bent section 134 that extends downward from the upper die 102(2), below the active side 118 of the upper die 102(2) in the vertical direction towards the package substrate 104, and that then turns upward towards the interposer 106.

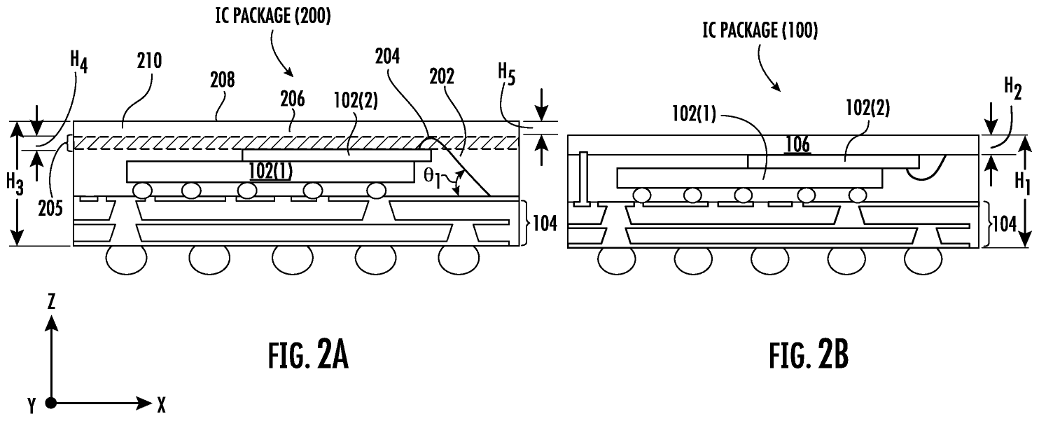

Note that although the IC package 100 in FIGS. 1A and 1B only include two dies 102(1), 102(2), other IC packages could be provided that include an interposer for electrical coupling to an upper die wherein such IC packages include more than two (2) dies. In this regard, FIG. 3A is a side view of an exemplary IC package 300 that includes three (3) stacked dies 302(1)-302(3) disposed between a package substrate 304 and an interposer 306. The first die 302(1) is considered a “lower” die in this example, meaning that is disposed below the second, “upper” die 302(2) and the third die 302(3) in the vertical, Z-axis direction as shown in FIG. 3A. The third die 302(3) is considered an “intermediate” die in this example, meaning that is disposed between the lower die 302(1) and the upper die 302(2) in the vertical, Z-axis direction as also shown in FIG. 3A. The lower die 302(1) is disposed adjacent to the package substrate 304. The upper die 302(2) is disposed adjacent to the interposer 306. An overmold 305 (e.g., an epoxy) surrounds the stacked dies 302(1)-302(3) between the interposer 306 and the package substrate 304. The stacked dies 302(1)-302(3) include ICs for performing electronic functions according to their design. For example, the lower die 302(1) may be a communications modem. The intermediate and upper dies 302(3), 302(2) may be a memory device that is designed to provide data storage and access to the modem in the lower die 302(1), such as for buffering of data to be modulated for transmission as radio-frequency (RF) signals and demodulated data from received RF signals.

The package substrate 304 supports the stacked dies 302(1)-302(3) and also includes metallization layers 308(1), 308(2) that each include metal interconnects 310(1), 310(2) (e.g., metal lines, metal traces, vias) that can provide electrical signal routing between external interconnects 312 (e.g., solder bumps) and the dies 302(1)-302(3). The metallization layers 308(1), 308(2) could be formed as laminate substrates that are bonded to each other and/or as RDLs. Although not shown, note that the package substrate 304 could also include a core section to be a cored substrate, as opposed to a coreless substrate. The package substrate 304 in this example include an external metallization layer 308(3) that has metal interconnects 310(3) exposed from the package substrate 304 wherein the external interconnects 312 can be coupled to the metal interconnects 310(3) to provide external signal routing access to the IC package 300. For example, the external interconnects 312 may be soldered to contacts on a PCB to physically mount the IC package on the PCB and to couple the IC package 300 to other circuitry. Certain metal interconnects 310(1), 310(2) in the package substrate 304 can also be designated to provide internal signal routing between the dies 302(1)-302(3) themselves.

With continuing reference to FIG. 3A, the stacked dies 302(1)-302(3) are electrically coupled to the package substrate 304 for signal routing. The lower die 302(1) in the IC package 300 is shown as being directly electrically coupled to the package substrate 304 through interconnect bumps 314. An active side 316 of the lower die 302(1) adjacent to the package substrate 304 is coupled to the interconnect bumps 314 which are coupled to the metal interconnects 310(1) in the upper metallization layer 308(1) of the package substrate 304. However, the intermediate and upper dies 302(3), 302(2) stacked above the lower die 302(1) are not located directly adjacent to the package substrate 304. Wire bonds could be employed to couple an active side 318 of an upper die 302(2) directly to the metal interconnects 310(1) in the upper metallization layer 308(1) of the package substrate 304. However, wire bonds may have to be oriented to extend above the upper die 302(2) in the vertical (Z-axis) direction to have sufficient clearance area to extend outward and then downward to the package substrate 304 without interfering with the intermediate and/or lower dies 302(3), 302(1) or other package components. Wire bonds may also require a minimum bend radius so as to not be damaged, which would require a certain additional clearance area in the IC package 300 above the upper die 302(2) to have sufficient area for such wire bonds and to accommodate their required minimum bend radius. This additional clearance area, if present, would contribute towards the overall height H₆ of the IC package 300 that may be undesired.

Thus, as shown in the additional side view of the IC package 300 in FIG. 3B, to reduce the height of the IC package 300 while still providing for the stacked dies 302(1)-302(3) to be electrically coupled to the package substrate 304, the IC package 300 in FIG. 3C includes the interposer 306. The interposer 306 provides electrical interface routing between one component and another, which in this case is between the upper die 302(1) and electrical interconnects 320 (e.g., metal pillars, metal posts, metal vias) coupling the interposer 306 to the package substrate 304. For example, the interposer 306 may include one or more metallization layers 322 that each include one or more metal interconnects that are electrically coupled to the upper die 302(1) and also electrically coupled to one or more electrical interconnects 320 for routing of electrical signals from the upper die 302(1) to the package substrate 304. In this manner, the upper die 302(2) is electrically coupled to the package substrate 304 for signal routing to the external interconnects 312 and/or to other metal interconnects 310(1), 310(2) in the metallization layers 308(1), 308(2) that are coupled to the intermediate and lower dies 302(3), 302(1) for die-to-die connections. As shown in FIG. 3B, in this example, one or more wires 324 are coupled (e.g., wire bonded) between the active side 318 of the upper die 302(2) and the interposer 306 to provide electrical interface connections between the upper die 302(2) and the interposer 306. The electrical interconnects 320 are coupled between the interposer 306 and the package substrate 304 to route electrical connections between the wires 324 coupled to the upper die 302(2) and the package substrate 304. In this manner, the upper die 302(1) can be electrically coupled to the package substrate 304 without requiring an additional clearance area for wire bonds to be coupled to the active side 318 of the upper die 302(1), extending up above the upper die 302(1) in the vertical (Z-axis) direction and then back down to the package substrate 304. The height H₇ of the interposer 306 adding to the overall height H₆ of the IC package 300 may be less than the additional height of overmold that would be needed to provide an additional clearance area above the upper die 302(2) needed for wire bonding the upper die 302(2) to the package substrate 304. For example, the height H₇ of the interposer 306 may be 50 micrometers (μm).

With continuing reference to FIG. 3B, the lower die 302(1) of the IC package 300 has an inactive side 326 on an opposite side of the active side 316. The intermediate die 302(3) of the IC package 300 has an inactive side 336 adjacent to the inactive side 326 of the lower die 302(1). The intermediate die 302(3) has an active side 338 on the opposite side of the inactive side 336 and adjacent to the active side 318 of the upper die 302(2). At least a portion of the inactive side 336 of the intermediate die 302(3) may be bonded (e.g., through an epoxy or compression bond) to at least a portion of the inactive side 326 of the lower die 302(1). At least a portion of the active side 318 of the upper die 302(2) may be bonded (e.g., through an epoxy or compression bond) to at least a portion of the active side 338 of the intermediate die 302(3). The upper die 302(2) has an inactive side 328 that is on an opposite side of the active side 318 of the upper die 302(2). The wires 324 are coupled to the active side 318 of the upper die 302(2) and also coupled the interposer 306 to electrically couple the upper die 302(2) to the interposer 306. In this example, the make room for the wires 324 to be coupled between the upper die 302(2) and the interposer 306, the upper die 302(2) is staggered to only be partially overlapping of the intermediate die 302(3) in the horizontal (X-axis) direction. In this regard, the active side 318 of the upper die 302(2) includes a first active side portion 330 overlapping a portion of the active side 338 of the intermediate die 302(2) in a vertical (Z-axis) direction and a second active side portion 332 not overlapping the intermediate die 302(3) in the vertical (Z-axis) direction. In this manner, there is room for the wires 324 to extend downward from the active side 318 of the upper die 302(2) towards the package substrate 304 and then bend back upwards towards the interposer 306 to then extend and couple to the interposer 306. This arrangement avoids a bent section 334 of the wires 324 extending above the upper die 302(2) in the vertical direction thereby requiring additional area above the upper die 302(2) to be reserved, which would increase the height of the package 300. In this example, the wires 324 include a concave bent section 334 that extends downward from the upper die 302(2), below the active side 318 of the upper die 302(2) in the vertical direction towards the package substrate 304, and that then turns upward towards the interposer 306.

Also, as shown in FIG. 3B, the intermediate die 302(3) is electrically coupled to the package substrate 304 in this example through wires 340, which may be wire bonds for example. Because the active side 338 of the intermediate die 302(3) includes a first active side portion 342 not overlapping the upper die 302(2) in the vertical (Z-axis) direction, there is room for the wires 340 to extend upward from the active side 338 of the intermediate die 302(3) towards the interposer 306 and then bend back downwards towards the package substrate 304 to then extend and couple to the package substrate 304. Alternatively, the intermediate die 302(3) could be reversed in orientation with its active side 338 adjacent to the lower die 302(1), and its inactive side 336 adjacent to the upper die 302(2). In this example, similar to the wires 324 coupling the upper die 302(2) to the interposer 306, the wires 340 could then be oriented to couple the active side 338 of the intermediate die 302(3) to the interposer 306. In this latter example scenario, the intermediate die 302(3) could be electrically coupled to the package substrate 304 through a connection between the interposer 306 and an electrical interconnect 320.

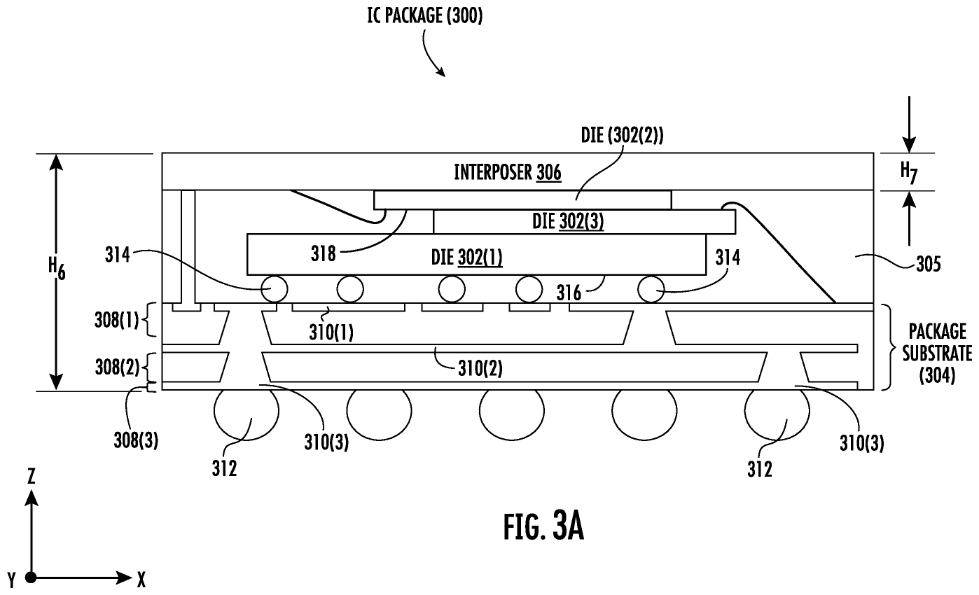

FIG. 4 is a flowchart illustrating an exemplary process 400 of fabricating IC package that includes stacked dies between a package substrate and an interposer, wherein a lower die is directly electrically coupled to the package substrate and an upper die is electrically coupled to the package substrate through an interposer for package height reduction. The exemplary process 400 in FIG. 4 could be employed to fabricate the IC packages 100, 300 in FIGS. 1A-1B and 3A-3B, respectively. The process 400 in FIG. 4 will be discussed in conjunction with the IC packages 100, 300 in FIGS. 1A-1B and 3A-3B.

In this regard, as shown in FIG. 4, one exemplary step in the process 400 is providing a package substrate 104, 304 (block 402 in FIG. 4). Another exemplary step in the process 400 is providing an interposer 106, 306 (block 404 in FIG. 4). Another exemplary step in the process 400 is electrically coupling a first die 102(1), 302(1) to the package substrate 104, 304 (block 406 in FIG. 4). Another exemplary step in the process 400 is disposing a second die 102(2), 302(2) between the first die 102(1), 302(1) and the interposer 106, 306 (block 408 in FIG. 4). Another exemplary step in the process 400 is coupling one or more second wires 124, 324 to the second die 102(2), 302(2) and the interposer 106, 306 (block 410 in FIG. 4). Another exemplary step in the process 400 is coupling one or more electrical interconnects 120, 320 to the package substrate 104, 304 and to the interposer 106, 306 to electrically couple a second wire 124, 324 among the one or more second wires 124, 324 to the package substrate 104, 304 (block 412 in FIG. 4).

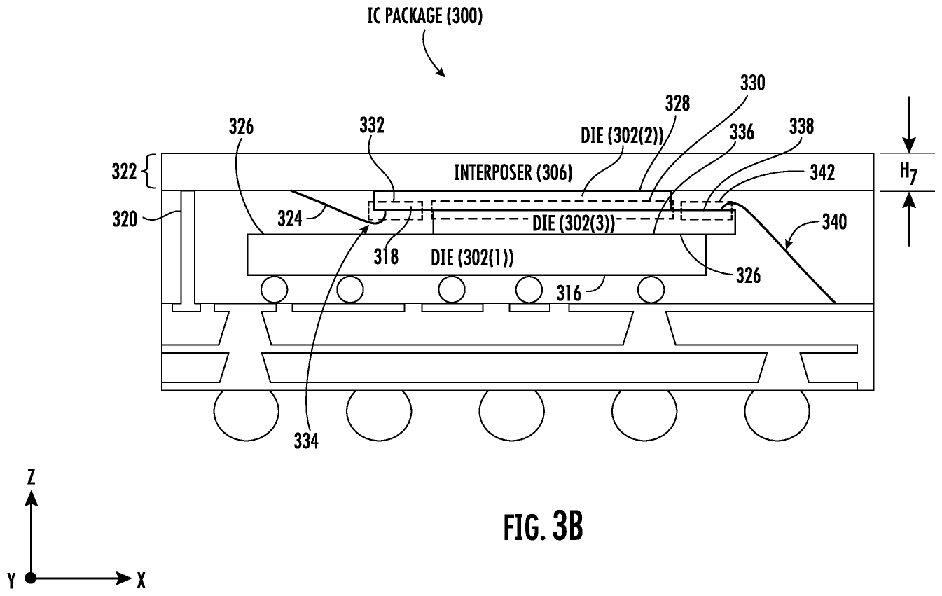

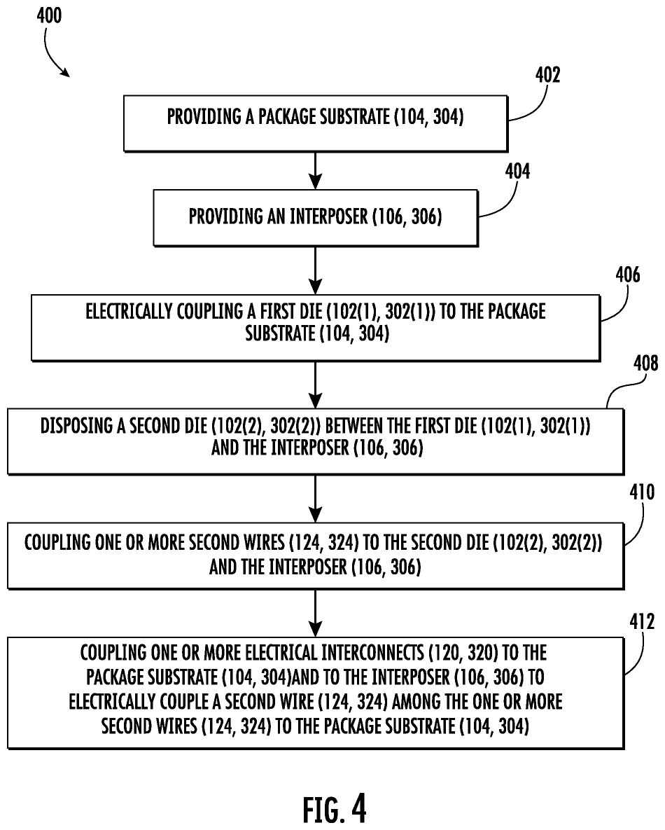

An IC package that includes a lower die directly electrically coupled to the package substrate and an upper die electrically coupled to the package substrate through an interposer for package height reduction can be fabricated as sub-assemblies that are then assembled together. For example, FIG. 5 is a flowchart illustrating an exemplary process 500 for fabricating an interposer and upper die sub-package to be included in an IC package that includes stacked dies between a package substrate and an interposer, wherein a lower die is directly electrically coupled to the package substrate and an upper die is electrically coupled to the package substrate through an interposer for package height reduction. This can include the IC packages 100, 300 in FIGS. 1A-1B and 3A-3B, respectively. FIGS. 6A-6C illustrate exemplary fabrication stages 600A-600C during fabrication of the interposer and upper die sub-package for an IC package, including, but not limited to, the IC packages 100, 300 in FIGS. 1A-1B and 3A-3B, and according to the exemplary fabrication process 500 in FIG. 5. The process 500 in FIG. 5 will be discussed in conjunction with the fabrication stages 600A-600C in FIGS. 6A-6C and in reference to the IC package 300 in FIGS. 3A-3B.

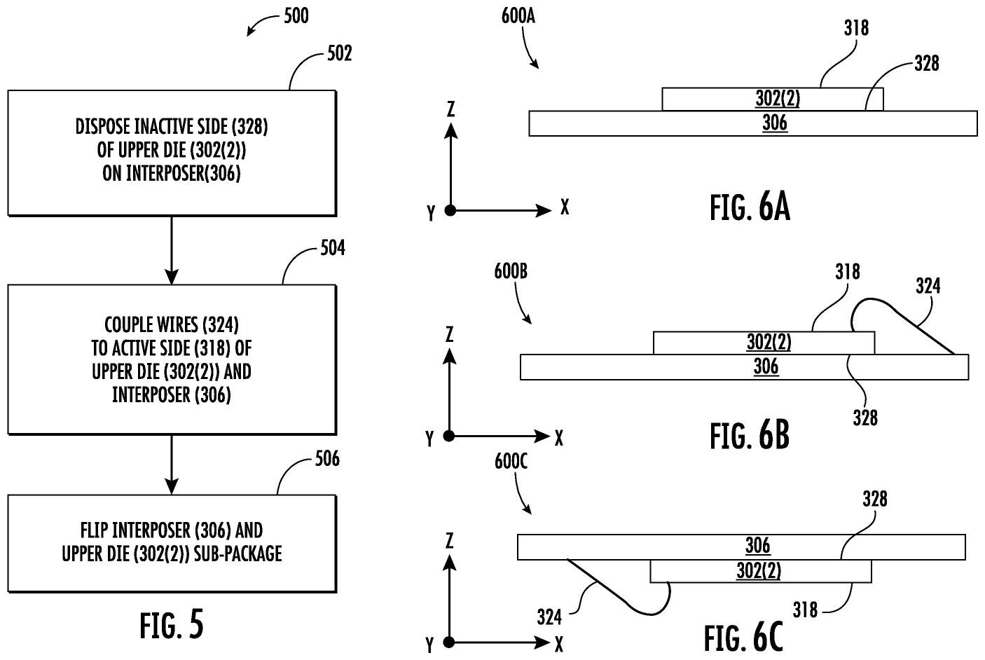

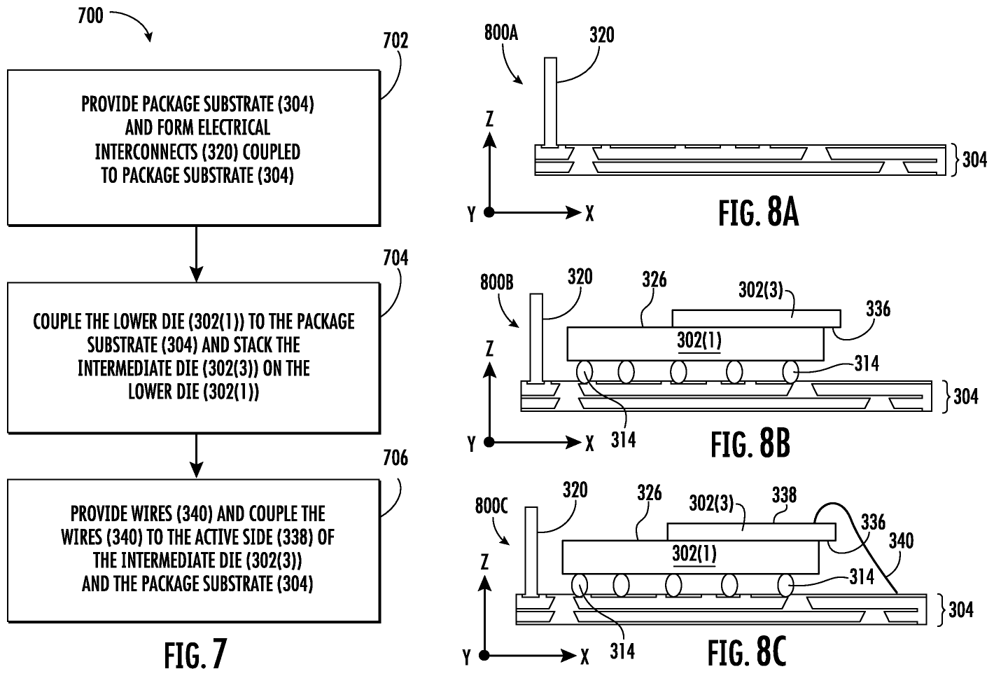

In this regard, as illustrated in the exemplary fabrication stage 600A in FIG. 6A, a first step in the process 500 to fabricate an interposer 106 and upper die 102(2) sub-package, can be to dispose the inactive side 328 of the upper die 102(2) on the interposer 106 (block 502 in FIG. 5). Then, as illustrated in the exemplary fabrication stage 600B in FIG. 6B, a next step in the process 500 can be to provide the wires 324 and couple (e.g., wire bond) the wires 324 to the active side 318 of the upper die 302(2) and the interposer 306 to provide the interposer 306 and upper die 302(2) sub-package (block 504 in FIG. 5). Then, as illustrated in the exemplary fabrication stage 600C in FIG. 6C, a next step in the process 500 can be to flip the interposer 306 and upper die 302(2) sub-package to prepare it to be disposed on a package substrate 304 and lower die 302(1) sub-package, as will next be described below with regard to FIGS. 7-8C.

FIG. 7 is a flowchart illustrating an exemplary process 700 for fabricating a package substrate and lower die sub-package to be included in an IC package that includes stacked dies between a package substrate and an interposer, wherein a lower die is directly electrically coupled to the package substrate and an upper die is electrically coupled to the package substrate through an interposer for package height reduction. This can include the IC packages 100, 300 in FIGS. 1A-1B and 3A-3B, respectively. FIGS. 8A-8C illustrate exemplary fabrication stages 800A-800C during fabrication of the package substrate and lower die sub-package for an IC package, including, but not limited to, the IC packages 100, 300 in FIGS. 1A-1B and 3A-3B, and according to the exemplary fabrication process in FIG. 7. The process 700 in FIG. 7 will be discussed in conjunction with the fabrication stages 800A-800C in FIGS. 8A-8C and in reference to the IC package 300 in FIGS. 3A-3B.

In this regard, as illustrated in the exemplary fabrication stage 800A in FIG. 8A, a first step in the process 700 to fabricate the package substrate 304 and lower die 302(2) sub-package can be to provide the package substrate 304 and form the electrical interconnects 320 coupled to the package substrate 304 (block 702 in FIG. 7). As illustrated in the exemplary fabrication stage 800B in FIG. 8B, a next step in the process 700 to fabricate the package substrate 304 and lower die 302(2) sub-package can be to couple the lower die 302(1) through interconnect bumps 314 to the package substrate 304 to stack the intermediate die 302(3) on the lower die 302(1) (block 704 in FIG. 7). The inactive side 336 of the intermediate die 302(3) can be bonded to the inactive side 326 of the lower die 302(1). As previously discussed, in this example, the intermediate die 302(3) is stacked on the lower die 302(1) such that the intermediate die 302(3) is only partially overlapping the lower die 302(1). This provides room for the wires 340 to be coupled to the active side 338 of the intermediate die 302(3) and the package substrate 304. As illustrated in the exemplary fabrication stage 800C in FIG. 8C, a next step in the process 700 to fabricate the package substrate 304 and lower die 302(2) sub-package, can be to provide the wires 340 and couple (e.g., wire bond) the wires to the active side 338 of the intermediate die 302(3) and the package substrate 304 to electrically couple the intermediate die 302(3) to the package substrate 304 (block 706 in FIG. 7).

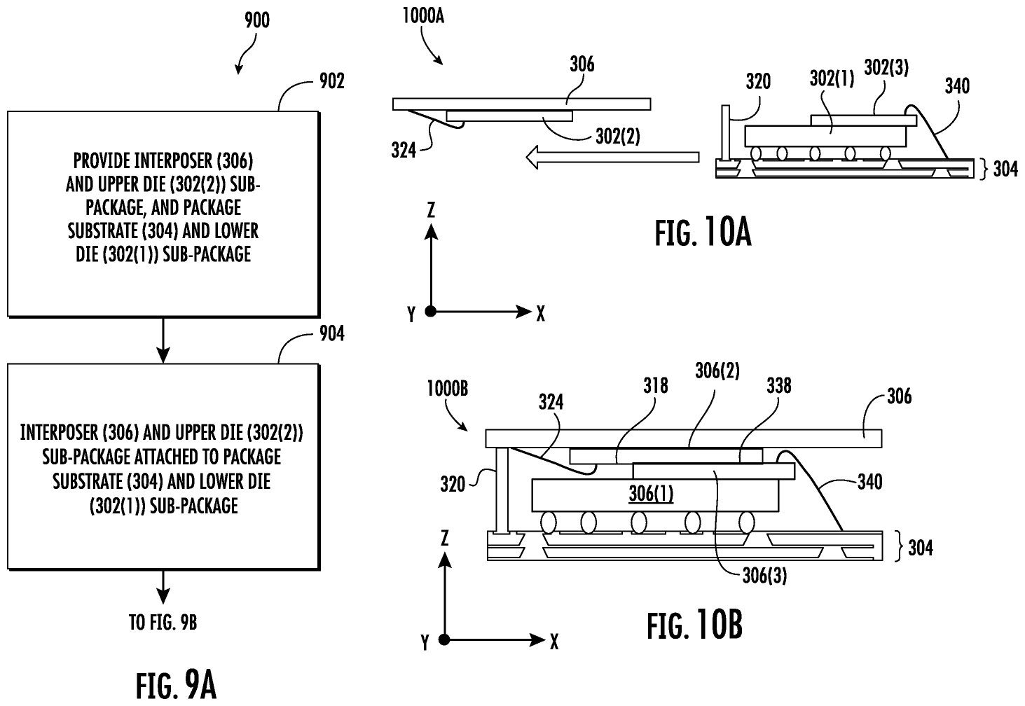

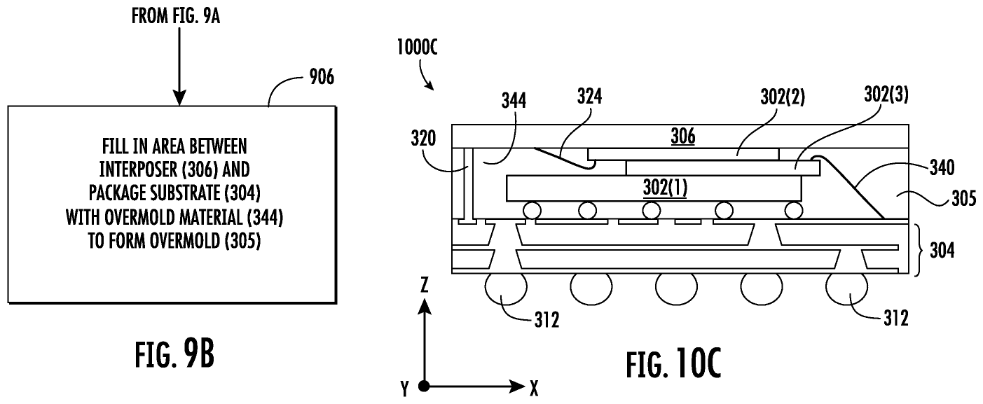

FIGS. 9A and 9B are a flowchart 900 illustrating an exemplary process for assembling an interposer and upper die sub-package, including, but not limited to, the interposer 306 and upper die 302(2) sub-package in FIG. 6C, with a package substrate and lower die sub-package, including, but not limited to, the package substrate 304 and lower die 302(1) sub-package in FIG. 8C, for fabricating an IC package. The fabricated IC package includes stacked dies between a package substrate and an interposer, wherein a lower die is directly electrically coupled to the package substrate and an upper die is electrically coupled to the package substrate through an interposer for package height reduction, including, but not limited to, the IC packages 100, 300 in FIGS. 1A-1B and 3A-3B. FIGS. 10A-10C illustrate exemplary fabrication stages 1000A-1000C during assembly of the interposer and upper die sub-package with a package substrate and lower die sub-package to form an IC package, including, but not limited to, the IC packages 100, 300 in FIGS. 1A-1B and 3A-3B, and according to the exemplary fabrication process in FIGS. 9A and 9B. The process 900 in FIGS. 9A and 9B will be discussed in conjunction with the fabrication stages 1000A-1000C in FIGS. 1000A-100C and in reference to the interposer 306 and upper die 302(2) sub-package in in FIGS. 3A-3B and 6C and the package substrate 304 and lower die 302(1) sub-package in FIG. 8C.

In this regard, as illustrated in the exemplary fabrication stage 1000A in FIG. 10A, a first step in the process 900 to fabricate the IC package 300 that includes the interposer 306 and upper die 302(2) sub-package in FIG. 6C with the package substrate 304 and lower die 302(1) sub-package FIG. 8C can be to provide the interposer 306 and upper die 302(2) sub-package in FIG. 6C with the package substrate 304 and lower die 302(1) sub-package in FIG. 8C (block 902 in FIG. 9A). As illustrated in the exemplary fabrication stage 1000B in FIG. 10B, a next step in the process 900 to fabricate the IC package 300 that includes the interposer 306 and upper die 302(2) sub-package in FIG. 6C with the package substrate 304 and lower die 302(1) sub-package in FIG. 8C can be to attach the interposer 306 to the electrical interconnect 320 and bond the upper die 302(2) to the intermediate die 302(3) so that the upper die 302(2) and intermediate die 302(3) are partially overlapping (block 904 in FIG. 9A). This is to provide room for wires 340 and 324 to electrically couple the respective intermediate and upper dies 302(3), 302(2) to the respective interposer 306 and package substrate 304. As previously discussed, in this example, the active side 318 of the upper die 302(2) is bonded to the active side 338 of the intermediate die 302(3). As illustrated in the exemplary fabrication stage 10000 in FIG. 10C, a next step in the process 900 to fabricate the IC package 300 that includes the interposer 306 and upper die 302(2) sub-package in FIG. 6C with the package substrate 304 and lower die 302(1) sub-package in FIG. 8C can be to fill in the area between the interposer 306 and the package substrate 304 with an overmold material 344 to form the overmold 305 (block 906 in FIG. 9B). The overmold 305 is formed around the dies 302(1)-302(3) and the bonding wires 324, 340 to protect and insulate these components.

An IC package with stacked dies between a package substrate and an interposer, wherein a lower die and intermediate dies are directly electrically coupled to the package substrate, and an upper die is electrically coupled to the package substrate through an interposer for package height reduction, including, but not limited, to the IC packages FIGS. 1A-1B, 3A-3B, 6A-6C, 8A-8C and 10A-10B, and according to the exemplary fabrication processes in FIGS. 5, 7, and 9A-9B, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

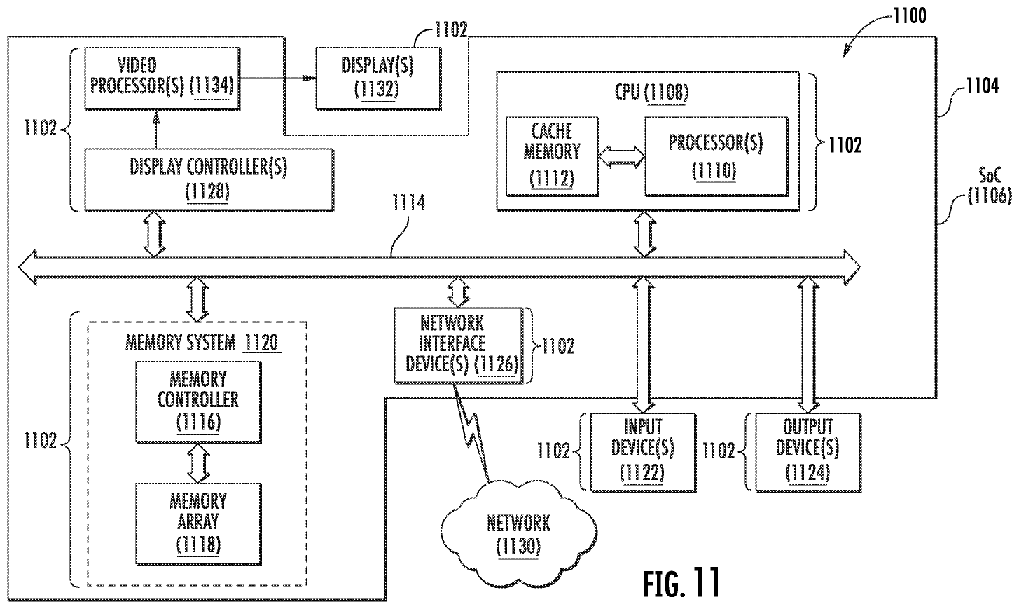

In this regard, FIG. 11 illustrates an example of a processor-based system 1100. The components of the processor-based system 1100 are ICs 1102. Some or all of the ICs 1102 in the processor-based system 1100 can be provided in an IC package with stacked dies between a package substrate and an interposer, wherein a lower die and intermediate dies are directly electrically coupled to the package substrate, and an upper die is electrically coupled to the package substrate through an interposer for package height reduction, including, but not limited, to the IC packages in FIGS. 1A-1B, 3A-3B, 6A-6C, 8A-8C and 10A-10B, and according to the exemplary fabrication processes in FIGS. 5, 7, and 9A-9B, and according to any aspects disclosed herein. In this example, the processor-based system 1100 may be formed as IC package 1104 and as a system-on-a-chip (SoC) 1106. The processor-based system 1100 includes a CPU 1108 that includes one or more processors 1110, which may also be referred to as CPU cores or processor cores. The CPU 1108 may have cache memory 1112 coupled to the CPU 1108 for rapid access to temporarily stored data. The CPU 1108 is coupled to a system bus 1114 and can intercouple master and slave devices included in the processor-based system 1100. As is well known, the CPU 1108 communicates with these other devices by exchanging address, control, and data information over the system bus 1114. For example, the CPU 1108 can communicate bus transaction requests to a memory controller 1116 as an example of a slave device. Although not illustrated in FIG. 11, multiple system buses 1114 could be provided, wherein each system bus 1114 constitutes a different fabric.

Other master and slave devices can be connected to the system bus 1114. As illustrated in FIG. 11, these devices can include a memory system 1120 that includes the memory controller 1116 and a memory array(s) 1118, one or more input devices 1122, one or more output devices 1124, one or more network interface devices 1126, and one or more display controllers 1128, as examples. Each of the memory system 1120, the one or more input devices 1122, the one or more output devices 1124, the one or more network interface devices 1126, and the one or more display controllers 1128 can be provided in the same or different circuit packages. The input device(s) 1122 can include any type of input device, including, but not limited to, input keys, switches, voice processors, etc. The output device(s) 1124 can include any type of output device, including, but not limited to, audio, video, other visual indicators, etc. The network interface device(s) 1126 can be any device configured to allow exchange of data to and from a network 1130. The network 1130 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1126 can be configured to support any type of communications protocol desired.

The CPU 1108 may also be configured to access the display controller(s) 1128 over the system bus 1114 to control information sent to one or more displays 1132. The display controller(s) 1128 sends information to the display(s) 1132 to be displayed via one or more video processors 1134, which process the information to be displayed into a format suitable for the display(s) 1132. The display controller(s) 1128 and video processor(s) 1134 can be included as IC package 1104 and the same or different circuit packages, and in the same or different circuit packages containing the CPU 1108 as an example. The display(s) 1132 can include any type of display, including, but not limited to, a cathode ray tube (CRT), a liquid crystal display (LCD), a plasma display, a light emitting diode (LED) display, etc.

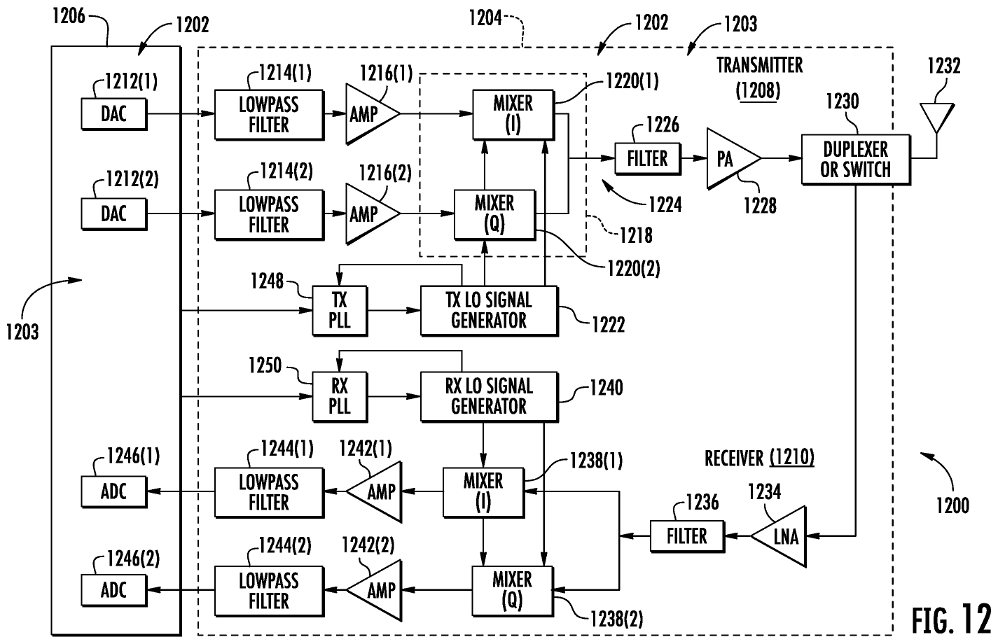

FIG. 12 illustrates an exemplary wireless communications device 1200 that includes radio frequency (RF) components formed from one or more ICs 1202, wherein any of the ICs 1202 can include IC package(s) 1203 with stacked dies between a package substrate and an interposer, wherein a lower die and intermediate dies are directly electrically coupled to the package substrate, and an upper die is electrically coupled to the package substrate through an interposer for package height reduction, including, but not limited, to the IC packages in FIGS. 1A-1B, 3A-3B, 6A-6C, 8A-8C and 10A-10B, and according to the exemplary fabrication processes in FIGS. 5, 7, and 9A-9B, and according to any aspects disclosed herein. The wireless communications device 1200 may include or be provided in any of the above-referenced devices, as examples. As shown in FIG. 12, the wireless communications device 1200 includes a transceiver 1204 and a data processor 1206. The data processor 1206 may include a memory to store data and program codes. The transceiver 1204 includes a transmitter 1208 and a receiver 1210 that support bi-directional communications. In general, the wireless communications device 1200 may include any number of transmitters 1208 and/or receivers 1210 for any number of communication systems and frequency bands. All or a portion of the transceiver 1204 may be implemented on one or more analog ICs, RFICs, mixed-signal ICs, etc.

The transmitter 1208 or the receiver 1210 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 1210. In the direct-conversion architecture, a signal is frequency-converted between RF and baseband in one stage. The super-heterodyne and direct-conversion architectures may use different circuit blocks and/or have different requirements. In the wireless communications device 1200 in FIG. 12, the transmitter 1208 and the receiver 1210 are implemented with the direct-conversion architecture.

In the transmit path, the data processor 1206 processes data to be transmitted and provides I and Q analog output signals to the transmitter 1208. In the exemplary wireless communications device 1200, the data processor 1206 includes digital-to-analog converters (DACs) 1212(1), 1212(2) for converting digital signals generated by the data processor 1206 into the I and Q analog output signals, e.g., I and Q output currents, for further processing.

Within the transmitter 1208, lowpass filters 1214(1), 1214(2) filter the I and Q analog output signals, respectively, to remove undesired signals caused by the prior digital-to-analog conversion. Amplifiers (AMPs) 1216(1), 1216(2) amplify the signals from the lowpass filters 1214(1), 1214(2), respectively, and provide I and Q baseband signals. An upconverter 1218 upconverts the I and Q baseband signals with I and Q transmit (TX) local oscillator (LO) signals through mixers 1220(1), 1220(2) from a TX LO signal generator 1222 to provide an upconverted signal 1224. A filter 1226 filters the upconverted signal 1224 to remove undesired signals caused by the frequency upconversion as well as noise in a receive frequency band. A power amplifier (PA) 1228 amplifies the upconverted signal 1224 from the filter 1226 to obtain the desired output power level and provides a transmit RF signal. The transmit RF signal is routed through a duplexer or switch 1230 and transmitted via an antenna 1232.

In the receive path, the antenna 1232 receives signals transmitted by base stations and provides a received RF signal, which is routed through the duplexer or switch 1230 and provided to a low noise amplifier (LNA) 1234. The duplexer or switch 1230 is designed to operate with a specific receive (RX)-to-TX duplexer frequency separation, such that RX signals are isolated from TX signals. The received RF signal is amplified by the LNA 1234 and filtered by a filter 1236 to obtain a desired RF input signal. Downconversion mixers 1238(1), 1238(2) mix the output of the filter 1236 with I and Q RX LO signals (i.e., LO_I and LO_Q) from an RX LO signal generator 1240 to generate I and Q baseband signals. The I and Q baseband signals are amplified by AMPs 1242(1), 1242(2) and further filtered by lowpass filters 1244(1), 1244(2) to obtain I and Q analog input signals, which are provided to the data processor 1206. In this example, the data processor 1206 includes analog-to-digital converters (ADCs) 1246(1), 1246(2) for converting the analog input signals into digital signals to be further processed by the data processor 1206.

In the wireless communications device 1200 of FIG. 12, the TX LO signal generator 1222 generates the I and Q TX LO signals used for frequency upconversion, while the RX LO signal generator 1240 generates the I and Q RX LO signals used for frequency downconversion. Each LO signal is a periodic signal with a particular fundamental frequency. A TX phase-locked loop (PLL) circuit 1248 receives timing information from the data processor 1206 and generates a control signal used to adjust the frequency and/or phase of the TX LO signals from the TX LO signal generator 1222. Similarly, an RX PLL circuit 1250 receives timing information from the data processor 1206 and generates a control signal used to adjust the frequency and/or phase of the RX LO signals from the RX LO signal generator 1240.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. An integrated circuit (IC) package, comprising:
   a package substrate;
   an interposer;
   a first die electrically coupled to the package substrate;
   a second die disposed between the first die and the interposer;
   one or more second wires coupled to the second die and the interposer; and
   one or more electrical interconnects coupled to the interposer and the package substrate and each electrically coupling a second wire among the one or more second wires to the package substrate.
2. The IC package of clause 1, wherein:
   the first die comprises a first active side adjacent to the package substrate and electrically coupled to the package substrate and a first inactive side on an opposite side of the first active side; and
   the second die comprises a second inactive side adjacent to the interposer and a second active side on an opposite side of the second inactive side, the one or more second wires electrically coupled to the interposer.
3. The IC package of clause 2, wherein the one or more second wires are coupled to the second active side of the second die and the interposer.
4. The IC package of clause 3, wherein:
   the second active side of the second die comprises:
      a first active side portion overlapping at least a portion of the first die in a vertical direction; and
      a second active side portion not overlapping the first die in the vertical direction; and
   the one or more second wires are coupled to the second active side portion of the second active side.
5. The IC package of clause 4, wherein each of the one or more second wires comprises a concave bent section that extends from the second die below the second die towards the package substrate and that turns upward towards the interposer.
6. The IC package of clause 4, wherein each of the one or more second wires comprises a concave bent section that turns upward towards the interposer.
7. The IC package of any of clauses 2 to 6, wherein at least a portion of the second active side of the second die is bonded to at least a portion of the first inactive side of the first die.
8. The IC package of any of clauses 1 to 7, wherein the second die is coupled to the first die in a stacked arrangement.
9. The IC package of clause 2, further comprising a compression bond between at least a portion of the second active side of the second die and at least a portion of the first inactive side of the first die.
10. The IC package of clause 2, further comprising an epoxy coupling at least a portion of the second active side of the second die to at least a portion of the first inactive side of the first die.
11. The IC package of any of clauses 1 to 10, further comprising one or more interconnect bumps each coupling the first die to the package substrate.
12. The IC package of any of clauses 1 to 11, further comprising one or more first wires electrically coupled to the first die and electrically coupled to the package substrate.
13. The IC package of any of clauses 1 to 12, wherein the first die is electrically coupled through the package substrate to at least one electrical interconnect among the one or more electrical interconnects, to electrically couple the first die to the second die.
14. The IC package of any of clauses 1 to 13, further comprising a third die disposed between the first die and the second die.
15. The IC package of clause 14, further comprising one or more third wires electrically coupled to the third die and the package substrate.
16. The IC package of clause 15, wherein each of the one or more third wires comprises a convex bent section that extends from the third die above the third die towards the interposer and that turns downward towards the package substrate.
17. The IC package of clause 14, further comprising one or more third wires electrically coupled to the third die and the interposer.
18. The IC package of clause 17, wherein each of the one or more third wires comprises a concave bent section that extends from the third die below the third die towards the package substrate and that turns upward towards the interposer.
19. The IC package of clause 17, further comprising one or more second electrical interconnects coupled to the interposer and the package substrate and each electrically coupled to a third wire among the one or more third wires.
20. The IC package of clause 19, wherein the third die is electrically coupled through the interposer to at least one electrical interconnect among the one or more electrical interconnects to electrically couple the third die to the first die.
21. The IC package of any of clauses 14 to 20, wherein:
   the first die comprises a first active side adjacent to the package substrate and electrically coupled to the package substrate and a first inactive side on an opposite side of the first active side;
   the second die comprises a second inactive side adjacent to the interposer and a second active side on an opposite side of the second inactive side; and
   the third die comprises a third active side and a third inactive side on an opposite side of the third active side.
22. The IC package of clause 21, wherein one or more third wires are coupled to the third active side of the third die and the package substrate.
23. The IC package of any of clauses 21 to 22, wherein:
   the third active side of the third die comprises:
      a first active side portion overlapping at east a portion of the first die in a vertical direction; and
      a second active side portion not overlapping the first die in the vertical direction; and
   one or more third wires are coupled to the second active side portion of the third active side.
24. The IC package of any of clauses 1 to 23 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
25. A method of fabricating an integrated circuit (IC) package, comprising:
   providing a package substrate;
   providing an interposer;
   electrically coupling a first die to the package substrate;
   disposing a second die between the first die and the interposer;
   coupling one or more second wires to the second die and the interposer; and
   coupling one or more electrical interconnects to the package substrate and to the interposer to electrically couple a second wire among the one or more second wires to the package substrate.
26. The method of clause 25, wherein:
   electrically coupling the first die to the package substrate comprises electrically coupling a first active side of the first die adjacent to the package substrate; and
   coupling the one or more second wires to the second die and the interposer comprises coupling the one or more second wires to a second active side of the second die adjacent to the interposer
27. The method of clause 26, wherein:
   disposing the second die between the first die and the interposer comprises orienting the second die to the first die such that a first active side portion of the second die overlaps at least a portion of the first die in a vertical direction and a second active side portion of the second die does not overlap the first die in the vertical direction; and
   coupling the one or more second wires to the second die and the interposer comprises coupling the one or more second wires to the second active side portion of the second active side.
28. The method of any of clauses 25 to 27, further comprising bonding the second die to the first die in a stacked arrangement.
29. The method of any of clauses 25 to 28, further comprising disposing a third die between the first die and the second die.
30. The method of clause 29, further comprising coupling one or more third wires to the third die and the package substrate.
31. The method of clause 30, wherein:
   disposing the third die between the first die and the second die comprises orienting the third die to the first die such that a first active side portion of the third die overlaps at least a portion of the first die in a vertical direction and a second active side portion of the third die does not overlap the first die in the vertical direction; and
   coupling the one or more third wires to the third die and the package substrate comprises coupling the one or more third wires to the second active side portion of the third die and the package substrate.
32. The method of clause 29, further comprising coupling one or more third wires to the third die and the interposer.
33. The method of clause 32, wherein:
   disposing the third die between the first die and the second die, comprises orienting the third die to the first die such that a first active side portion of the third die overlaps at least a portion of the first die in a vertical direction and a second active side portion of the third die does not overlap the first die in the vertical direction; and
   coupling the one or more third wires to the third die and the interposer comprises coupling the one or more third wires to the second active side portion of the third die and the interposer,
34. The method of any of clauses 25 to 33, wherein electrically coupling the first die to the package substrate comprises coupling one or more die interconnects coupled to a first active side of the first die to the package substrate.
35. The method of clause 34, further comprising:
   coupling a third die to a first inactive side of the first die on an opposite side of the first active side; and
   electrically coupling the third die to the package substrate.
36. The method of any of clauses 25 to 35, wherein disposing the second die between the first die and the interposer further comprises connecting a second inactive side of the second die to the interposer.

What is claimed is:

1. An integrated circuit (IC) package, comprising:
a package substrate;
an interposer;
a first die electrically coupled to the package substrate;
a second die disposed between the first die and the interposer;
one or more second wires coupled to the second die and the interposer; and
one or more electrical interconnects coupled to the interposer and the package substrate and each electrically coupling a second wire among the one or more second wires to the package substrate.

2. The package of claim 1, wherein:
the first die comprises a first active side adjacent to the package substrate and electrically coupled to the package substrate and a first inactive side on an opposite side of the first active side; and
the second die comprises a second inactive side adjacent to the interposer and a second active side on an opposite side of the second inactive side, the one or more second wires electrically coupled to the interposer.

3. The IC package of claim 2, wherein the one or more second wires are coupled to the second active side of the second die and the interposer.

4. The IC package of claim 3, wherein:
the second active side of the second die comprises:
a first active side portion overlapping at least a portion of the first die in a vertical direction; and
a second active side portion not overlapping the first die in the vertical direction; and
the one or more second wires are coupled to the second active side portion of the second active side.

5. The IC package of claim 4, wherein each of the one or more second wires comprises a concave bent section that extends from the second die below the second die towards the package substrate and that turns upward towards the interposer.

6. The IC package of claim 4, wherein each of the one or more second wires comprises a concave bent section that turns upward towards the interposer.

7. The IC package of claim 2, wherein at least a portion of the second active side of the second die is bonded to at least a portion of the first inactive side of the first die.

8. The IC package of claim 1, wherein the second die is coupled to the first die in a stacked arrangement.

9. The IC package of claim 2, further comprising a compression bond between at least a portion of the second active side of the second die and at least a portion of the first inactive side of the first die.

10. The IC package of claim 2, further comprising an epoxy coupling at least a portion of the second active side of the second die to at least a portion of the first inactive side of the first die.

11. The IC package of claim 1, further comprising one or more interconnect bumps each coupling the first die to the package substrate.

12. The IC package of claim 1, further comprising one or more first wires electrically coupled to the first die and electrically coupled to the package substrate.

13. The IC package of claim 1, wherein the first die is electrically coupled through the package substrate to at least one electrical interconnect among the one or more electrical interconnects, to electrically couple the first die to the second die.

14. The IC package of claim 1, further comprising a third die disposed between the first die and the second die.

15. The IC package of claim 14, further comprising one or more third wires electrically coupled to the third die and the package substrate.

16. The package of claim 15, wherein each of the one or more third wires comprises a convex bent section that extends from the third die above the third die towards the interposer and that turns downward towards the package substrate.

17. The IC package of claim 14, further comprising one or more third wires electrically coupled to the third die and the interposer.

18. The IC package of claim 17, wherein each of the one or more third wires comprises a concave bent section that extends from the third die below the third die towards the package substrate and that turns upward towards the interposer.

19. The IC package of claim 17, further comprising one or more second electrical interconnects coupled to the interposer and the package substrate and each electrically coupled to a third wire among the one or more third wires.

20. The IC package of claim 19, wherein the third die is electrically coupled through the interposer to at least one electrical interconnect among the one or more electrical interconnects to electrically couple the third die to the first die.

21. The IC package of claim 14, wherein:
the first die comprises a first active side adjacent to the package substrate and electrically coupled to the package substrate and a first inactive side on an opposite side of the first active side;
the second die comprises a second inactive side adjacent to the interposer and a second active side on an opposite side of the second inactive side; and
the third die comprises a third active side and a third inactive side on an opposite side of the third active side.

22. The IC package of claim 21, wherein one or more third wires are coupled to the third active side of the third die and the package substrate.

23. The IC package of claim 21, wherein:
the third active side of the third die comprises:
a first active side portion overlapping at least a portion of the first die in a vertical direction; and
a second active side portion not overlapping the first die in the vertical direction; and
one or more third wires are coupled to the second active side portion of the third active side.

24. The IC package of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

75. A method of fabricating an integrated circuit (IC) package, comprising:
providing a package substrate;
providing an interposer;
electrically coupling a first die to the package substrate;
disposing a second die between the first die and the interposer;
coupling one or more second wires to the second die and the interposer; and
coupling one or more electrical interconnects to the package substrate and to the interposer to electrically couple a second wire among the one or more second wires to the package substrate.

26. The method of claim 25, wherein:
electrically coupling the first die to the package substrate comprises electrically coupling a first active side of the first die adjacent to the package substrate; and
coupling the one or more second wires to the second die and the interposer comprises coupling the one or more second wires to a second active side of the second die adjacent to the interposer

27. The method of claim 26, wherein:
disposing the second die between the first die and the interposer comprises orienting the second die to the first die such that a first active side portion of the second die overlaps at least a portion of the first die in a vertical direction and a second active side portion of the second die does not overlap the first die in the vertical direction; and
coupling the one or more second wires to the second die and the interposer comprises coupling the one or more second wires to the second active side portion of the second active side.

28. The method of claim 25, further comprising bonding the second die to the first die in a stacked arrangement.

29. The method of claim 25, further comprising disposing a third die between the first die and the second die.

30. The method of claim 29, further comprising coupling one or more third wires to the third die and the package substrate.

31. The method of claim 30, wherein:
disposing the third die between the first die and the second die comprises orienting the third die to the first die such that a first active side portion of the third die overlaps at least a portion of the first die in a vertical direction and a second active side portion of the third die does not overlap the first die in the vertical direction; and
coupling the one or more third wires to the third die and the package substrate comprises coupling the one or more third wires to the second active side portion of the third die and the package substrate.

32. The method of claim 29, further comprising coupling one or more third wires to the third die and the interposer.

33. The method of claim 32, wherein:
disposing the third die between the first die and the second die, comprises orienting the third die to the first die such that a first active side portion of the third die overlaps at least a portion of the first die in a vertical direction and a second active side portion of the third die does not overlap the first die in the vertical direction; and
coupling the one or more third wires to the third die and the interposer comprises coupling the one or more third wires to the second active side portion of the third die and the interposer.

34. The method of claim 25, wherein electrically coupling the first die to the package substrate comprises coupling one or more die interconnects coupled to a first active side of the first die to the package substrate.

35. The method of claim 34, further comprising:
coupling a third die to a first inactive side of the first die on an opposite side of the first active side; and
electrically coupling the third die to the package substrate.

36. The method of claim 25, wherein disposing the second die between the first die and the interposer further comprises connecting a second inactive side of the second die to the interposer.
